(19) United States
(12) Patent Application Publication
(10) Pub. No.: US 2025/0206948 A1
(43) Pub. Date: Jun. 26, 2025

(54) CONDENSATION-CURABLE SILICONE RESIN COMPOSITION AND DIE ATTACH MATERIAL FOR OPTICAL SEMICONDUCTOR APPARATUS

(71) Applicant: SHIN-ETSU CHEMICAL CO., LTD., Tokyo (JP)

(72) Inventors: Tsubasa NISHIMURA, Annaka-shi (JP); Tatsuya YAMAZAKI, Tomioka-shi (JP)

(73) Assignee: SHIN-ETSU CHEMICAL CO., LTD., Tokyo (JP)

(21) Appl. No.: 18/958,216

(22) Filed: Nov. 25, 2024

(30) Foreign Application Priority Data
Dec. 20, 2023 (JP) 2023-214375

(51) Int. Cl. C08L 83/04; C08K 3/36

(52) U.S. Cl. CPC C08L 83/04; C08K 3/36; C08L 2203/20

(57) ABSTRACT

A condensation-curable silicone resin composition that produces a resin cured product with high hardness, high resin strength and excellent adhesion capability with respect to substrates, including: (A) a polyorganosiloxane having hydroxyl group and hydrolysable group represented by formula (1), in an amount of 100 parts by mass, CH₃Si(OR)ₐ(OH)_{b}O_{(3-a-b)/2} (1); (B) an organosilicate oligomer, which is a partially hydrolyzed condensate of tetraalkyl orthosilicate, in an amount of 10 to 50 parts by mass relative to 100 parts by mass of the component (A); (C) a linear polyorganosiloxane having epoxy group and hydrosilyl group in the molecule represented by formula (2), in an amount of 0.1 to 10 parts by mass relative to 100 parts by mass of total of component (A) and component (B),

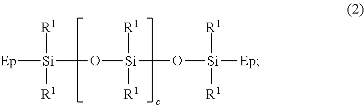

and (D) an inorganic filler in an amount of 1 to 10 parts by mass relative to 100 parts by mass of the component (A).

### TECHNICAL FIELD

The present invention relates to a condensation-curable silicone resin composition and a die attach material for optical semiconductor apparatuses.

### BACKGROUND ART

Die attach materials are used to solidify semiconductor chips on substrates. In terms of reliability, certain properties such as high adhesion strength and high adhesion properties are required for die attach materials. Among die attach materials, addition-curable silicone resin compositions, such as methyl silicone resin compositions with high heat resistance and high light resistance are often used as die attach materials for LED chips. However, LED devices with LED chips of 300 μm or less, which are smaller than the standard-sized LED chips of 600 μm have recently emerged, and therefore there have been problems, for example, that the conventional methyl silicone-based addition-curable resin compositions disclosed in Patent Document 1 and Patent Document 2 do not satisfy the required value of capability in holding LED chips. Further, an unresolved issue for addition-curable resin compositions is the limited usage environment due to the risk of curing inhibition caused by the nature of the reaction.

On the other hand, a method of using a conventional condensation-curable silicone resin composition, such as that disclosed in Patent Document 3, as a die attach material for LED devices has been disclosed. However, some issues have been pointed out, especially for small-sized LED chips, regarding the instability of adhesion strength and fracture mode of resin during adhesion tests, and there is also a demand for improving adhesion strength.

### CITATION LIST

### Patent Literature

Patent Document 1: JP 2018-131583 A
Patent Document 2: WO 2018/155131 A1
Patent Document 3: WO 2017/122762 A1

### SUMMARY OF INVENTION

### Technical Problem

The present invention was made in view of such circumstances, and an object of the present invention is to provide a condensation-curable silicone resin composition that can produce a resin cured product with high hardness and high resin strength and also has excellent adhesion capability with respect to substrates.

### Solution to Problem

In order to solve the above problem, the present invention provides a condensation-curable silicone resin composition, comprising:
(A) a polyorganosiloxane having hydroxyl group and hydrolysable group represented by the following formula (1), in an amount of 100 parts by mass,

CH₃Si(OR)ₐ(OH)_{b}O_{(3-a-b)/2} (1)

wherein R represents a same or different alkyl group having 1 to 6 carbon atoms, and satisfies 0≤a≤0.4, 0.001≤b≤0.5, 0.001≤a+b≤0.9;
(B) an organosilicate oligomer, which is a partially hydrolyzed condensate of tetraalkyl orthosilicate, in an amount of 10 to 50 parts by mass relative to 100 parts by mass of the component (A);
(C) a linear polyorganosiloxane having epoxy group and hydrosilyl group in the molecule represented by the following formula (2), in an amount of 0.1 to 10 parts by mass relative to 100 parts by mass of total of component (A) and component (B),

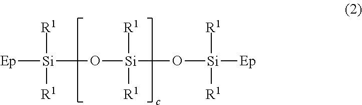

wherein R¹ is independently a hydrogen atom, an alkyl group having 1 to 12 carbon atoms, or an epoxy-containing organic group; c is a number satisfying 1≤c≤260; and Ep is independently an organic group having one or more epoxy groups in a substituent, provided that at least one of the R¹ is a hydrogen atom; and
(D) an inorganic filler in an amount of 1 to 10 parts by mass relative to 100 parts by mass of the component (A).

Such a condensation-curable silicone resin composition will produce a resin cured product with high hardness and high resin strength, as well as excellent adhesion capability with respect to the substrate.

In the condensation-curable silicone resin composition of the present invention, the alkyl group of the tetraalkyl orthosilicate of the component (B) preferably has 1 to 6 carbon atoms.

Such a condensation-curable silicone resin composition is likely to have higher hardness and higher resin strength, and is also preferable in terms of reactivity and cost.

In the condensation-curable silicone resin composition of the present invention, the component (C) preferably has a weight average molecular weight of 1,000 to 20,000 and an epoxy equivalent of 400 to 650 g/mol.

Such a condensation-curable silicone resin composition has no risk of cloudy appearance, and ensures sufficient adhesion capability with respect to the substrate.

The condensation-curable silicone resin composition of the present invention preferably further comprising a condensation-curing catalyst as a component (E).

Such a condensation-curable silicone resin composition can be efficiently cured.

The present invention also provides a die attach material for an optical semiconductor apparatus, which includes the condensation-curable silicone resin composition of the present invention.

Such a die attach material for optical semiconductor apparatuses can provide a highly reliable LED device because of its excellent adhesion strength even for small-sized LED chips.

### Advantageous Effects of Invention

According to the condensation-curable silicone resin composition of the present invention, when the composition is used as a die attach material for LED, due to its excellent adhesion strength even for small-sized LED chips, it makes it possible to provide a highly reliable LED device. Further, it is unlikely that its usage environment is limited due to the nature of the reaction. Therefore, the condensation-curable silicone resin composition of the present invention is extremely useful as a die attach material for LEDs.

### DESCRIPTION OF EMBODIMENTS

As mentioned above, there has been a need to develop a condensation-curable silicone resin composition with excellent adhesion strength even for small-sized LED chips.

As a result of intensive study to solve the problems described above, the present inventions found that a condensation-curable silicone resin composition containing the components (A), (B), (C), and (D) described above has an excellent adhesion capability with respect to substrates and exhibits high adhesion strength even in small-sized LED chips. With this finding, the inventors completed the present invention.

Specifically, the present invention is a condensation-curable silicone resin composition, comprising:
(A) a polyorganosiloxane having hydroxyl group and hydrolysable group represented by the following formula (1), in an amount of 100 parts by mass,

CH₃Si(OR)ₐ(OH)_{b}O_{(3-a-b)/2} (1)

wherein R represents a same or different alkyl group having 1 to 6 carbon atoms, and satisfies 0≤a≤0.4, 0.001≤b≤0.5, 0.001≤a+b≤0.9;
(B) an organosilicate oligomer, which is a partially hydrolyzed condensate of tetraalkyl orthosilicate, in an amount of 10 to 50 parts by mass relative to 100 parts by mass of the component (A);
(C) a linear polyorganosiloxane having epoxy group and hydrosilyl group in the molecule represented by the following formula (2), in an amount of 0.1 to 10 parts by mass relative to 100 parts by mass of total of component (A) and component (B),

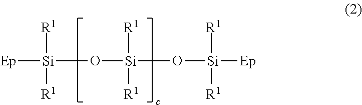

wherein R¹ is independently a hydrogen atom, an alkyl group having 1 to 12 carbon atoms, or an epoxy-containing organic group; c is a number satisfying 1≤c≤260; and Ep is independently an organic group having one or more epoxy groups in a substituent, provided that at least one of the R¹ is a hydrogen atom; and
(D) an inorganic filler in an amount of 1 to 10 parts by mass relative to 100 parts by mass of the component (A).

The present invention is described below in detail; however, the present invention is not limited to the examples described below.

(A) Polyorganosiloxane having Hydroxyl Group and Hydrolysable Group

The component (A) is a polyorganosiloxane having hydroxyl group and hydrolysable group represented by the following formula (1),

CH₃Si(OR)ₐ(OH)_{b}O_{(3-a-b)/2} (1)

wherein R represents a same or different alkyl group having 1 to 6 carbon atoms, and satisfies 0≤a≤0.4, 0.001≤b≤0.5, 0.001≤a+b≤0.9.

In the formula (1) above, examples of the alkyl group having 1 to 6 carbon atoms represented by R include methyl group, ethyl group, propyl group, isopropyl group, butyl group, isobutyl group, tert-butyl group, pentyl group, neopentyl group, hexyl group, and cyclohexyl group. Among these, methyl group is particularly preferable as the R above from the viewpoint of reactivity or cost.

The method for producing the polyorganosiloxane represented by the formula (1) above is not particularly limited. For example, the polyorganosiloxane can be synthesized by hydrolysis condensation of corresponding alkoxysilane under acidic conditions.

In the formula (1) above, the content “a” of the hydrolysable group (OR) directly bonded to silicon atom is 0≤a≤0.4, preferably 0.05≤a≤0.3. If “a” is more than 0.4, the strength of the cured product to be obtained may undesirably decrease.

In the formula (1) above, the content “b” of the hydroxyl group (OH) directly bonded to silicon atom is 0.001≤b≤0.5, preferably 0.005 b 0.4. If “b” is less than 0.001, the reactivity undesirably decreases, and if “b” is more than 0.5, the storage stability of the cured product undesirably decreases.

Further, the content “a+b,” i.e., the contents of hydroxyl groups and hydrolysable groups directly bonded to silicon atoms constituting the main chain structure of the polymer, is in the range of 0.001≤a+b≤0.9, preferably in the range of 0.06≤a+b<0.8.

As is apparent from the formula (1) above, the component (A) of the present invention is a polyorganosiloxane only having T units (trifunctional siloxane units).

The weight average molecular weight Mw of the component (A) above based on GPC is preferably 1,000 to 10,000, more preferably 2,000 to 6,000. A molecular weight range of 1,000 to 10,000 is preferable because it ensures sufficient resin strength as a die attach material as well as a practical range of viscosity. The weight average molecular weight referred to in the present invention designates a weight average molecular weight determined by gel permeation chromatography (GPC) under the following conditions using polystyrene as the standard material.

### Measurement Conditions

Developing solvent: tetrahydrofuran (THF)
Flow rate: 0.6 mL/min
Detector: differential refractive index detector (RI)
Column: TSK Guardcolumn SuperH-L
TSKgel SuperH4000 (6.0 mml. D.×15 cm×1)
TSKgel SuperH3000 (6.0 mml. D.×15 cm×1)
TSKgel SuperH2000 (6.0 mml. D.×15 cm×1)
(all manufactured by Tosoh Corporation)
Column temperature: 40° C.
Sample injection amount: 20 μl (0.5 mass % THF solution)
   (B) Organosilicate Oligomer, which is a Partially Hydrolyzed Condensate of Tetraalkyl Orthosilicate

The component (B) is an organosilicate oligomer, which is a partially hydrolyzed condensate of tetraalkyl orthosilicate. The alkyl group preferably has 1 to 6 carbon atoms. Examples thereof include methyl group, ethyl group, propyl group, isopropyl group, butyl group, isobutyl group, tert-butyl group, pentyl group, neopentyl group, hexyl group, and cyclohexyl group. Among these, methyl group or ethyl group is particularly preferable from the viewpoint of reactivity or cost.

The number “n,” which is the number of monomer units of the organosilicate oligomer is not particularly limited; however, “n” is preferably in the range of 1≤n≤20, more preferably in the range of 3≤n≤10. If the number “n” of monomer units is equal to or less than 20, appropriate viscosity can be obtained and excellent handleability of the resin composition can be ensured.

In the condensation-curable silicone resin composition of the present invention, the amount of the component (B) is 10 to 50 parts by mass, preferably 20 to 45 parts by mass, relative to 100 parts by mass of the component (A). If the amount of the component (B) is less than 10 parts by mass, the strength of the resin may decrease, and if the amount of the component (B) is more than 50 parts by mass, the volatile components due to the condensation reaction undesirably excessively increase.

The method for producing the organosilicate oligomer described above is not particularly limited. The organosilicate oligomer can be synthesized by hydrolysis condensation of corresponding tetraalkyl orthosilicate under acidic conditions.

### <(C) Linear Polyorganosiloxane Having Epoxy Group and Hydrosilyl Group>

The component (C) is a linear polyorganosiloxane having epoxy group and hydrosilyl group in the molecule, represented by the following formula (2),

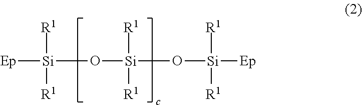

wherein R¹ is independently a hydrogen atom, an alkyl group having 1 to 12 carbon atoms, or an epoxy-containing organic group; c is a number satisfying 1≤c≤260; and Ep is independently an organic group having one or more epoxy groups in a substituent, provided that one or more of the R¹ is a hydrogen atom.

The linear polyorganosiloxane represented by the formula (2) above ensures improved adhesion to the substrate due to the effects of the hydrosilyl group in the side chain and the epoxy group in the terminal.

In the formula (2) above, examples of the alkyl group having 1 to 12 carbon atoms represented by R¹ include methyl group, ethyl group, propyl group, isopropyl group, butyl group, isobutyl group, tert-butyl group, pentyl group, neopentyl group, hexyl group, cyclohexyl group, octyl group, nonyl group, and decyl group. Among these, methyl group is particularly preferable as the R¹ from the viewpoint of cost.

The range of “c” in the formula (2) above is a number satisfying 1≤c≤260, preferably in the range of 10≤c≤100. If “c” is more than 260, the adhesion undesirably may become insufficient.

Further, the weight average molecular weight of the component (C) above ranges from 1,000 to 20,000, preferably 4,000 to 10,000. If the weight average molecular weight is equal to or less than 20,000, there is no risk of the silicone resin cured product appearing cloudy. If the weight average molecular weight is equal to or more than 1,000, sufficient adhesion to the substrate can be ensured.

Furthermore, the epoxy equivalent of the component (C) above is preferably in the range of 400 to 650 g/mol, more preferably in the range of 500 to 600 g/mol. If the epoxy equivalent is equal to or less than 650 g/mol, there is no risk of the silicone resin cured product appearing cloudy. If the epoxy equivalent is equal to or more than 400 g/mol, sufficient adhesion to the substrate can be ensured.

In the condensation-curable silicone resin composition of the present invention, the amount of the component (C) is 0.1 to 10 parts by mass, preferably 1.0 to 8 parts by mass, relative to 100 parts by mass of the total of the component (A) and the component (B). If the amount of the component (C) is more than 10 parts by mass relative to 100 parts by mass of the total of the component (A) and the component (B), the resulting silicone resin cured product has a cloudy appearance. If the amount of the component (C) is less than 0.1 parts by mass relative to 100 parts by mass of the total of the component (A) and the component (B), adhesion to the substrate becomes insufficient.

The method for producing the component (C) above is not particularly limited. The component (C) can be synthesized, for example, by a hydrosilylation reaction of a polyoorganosiloxane compound having a hydrosilyl group at the terminal and an epoxy compound having alkenyl group in the presence of a catalyst.

The structure of the polyorganosiloxane compound having a hydrosilyl group at the terminal is not particularly limited. As an example, a linear polyorganosiloxane compound represented by the following formula may be used,

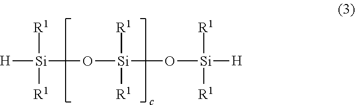

wherein R¹ is independently a hydrogen atom or an alkyl group having 1 to 12 carbon atoms, and satisfies 1≤c≤260.

The epoxy compound having alkenyl group is not particularly limited. Examples thereof include epoxy compounds represented by the following formula.

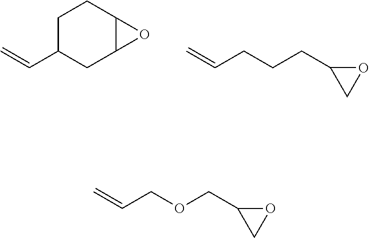

### (D) Inorganic Filler

The component (D) of the present invention is an inorganic filler. The purpose of using inorganic filler is to improve the strength of the cured product to be obtained and to impart thixotropy, thereby improving the coating workability of die attach materials. Examples of inorganic filler include fumed silica and fumed titanium dioxide. In particular, fumed silica is suitably used as an inorganic filler from the viewpoint of transparency of the cured product to be obtained.

The amount of the (D) inorganic filler to be used is in the range of 1 to 10 parts by mass, preferably in the range of 2 to 8 parts by mass, relative to 100 parts by mass of the component (A). If the amount of the inorganic filler is less than 1 part by mass, sufficient strength may not be obtained. If the amount of the inorganic filler is more than 10 parts by mass, the viscosity may undesirably become excessively large.

In particular, when fumed silica is used as an inorganic filler, it is desirable that the silica surface be treated with a hydrophobic group from the viewpoint of compatibility with silicone resin. Specific examples of hydrophobic group include alkylsilyl groups such as trimethylsilyl group and dimethylsilyl group.

Further, the surface treatment also provides an effect of suppressing the interaction between the epoxy group in the component (C) and the hydroxysilyl group on the surface of fumed silica, thereby improving the storage stability. For this reason, it is preferable to use fumed silica that has undergone sufficient surface treatment. More specifically, it is preferable to use fumed silica with a BET specific surface area of equal to or more than 150 m²/g and equal to or less than 290 m²/g, preferably equal to or more than 170 m²/g and equal to or less than 230 m²/g. Examples of commercially available fumed silica surface-treated with the alkylsilyl group include R812 (specific surface area: 230-290 m²/g) and RX300 (specific surface area: 180-220 m²/g), which are surface-treated with a trimethylsilyl group, and R976 (specific surface area: 225-275 m²/g) and R976S (specific surface area: 215-265 m²/g), which are surface-treated with a dimethylsilyl group, available from Nippon Aerosil Co., Ltd.

### (E) Condensation-Curing Catalyst

The condensation-curable silicone composition of the present invention contains the above-mentioned components (A), (B), (C), and (D) as essential components, and may also contain (E) a condensation-curing catalyst and the like, as needed. The condensation-curing catalyst is a component that accelerates the reaction by which a hydrolysable silyl group, such as an alkoxysilyl group and a silanol group, contained in the organopolysiloxane described above undergo hydrolysis condensation by the moisture in the air, accelerates the subsequent dehydration condensation reaction between silanols, thereby accelerating the curing of the composition. The condensation-curing catalyst is added to efficiently cure the condensation-curable silicone composition of the present invention.

The amount of the component (E) to be added is not particularly limited; however, in view of adjusting the curing speed to an appropriate range to produce a cured product with desired properties and improving workability during the coating, a metal element amount t (ppm) added to 100 parts by mass of the component (A) is in the range of 0 t 1,000, preferably 100 t 500. If the catalyst amount t is equal to or less than 1,000, moderate storage stability is also obtained.

The curing catalyst is not particularly limited insofar as it is a general curing catalyst used for curing condensation-curable compositions. Examples of the curing catalyst include tin, titanium, zirconium, zinc, aluminum and similar organic carboxylates, organic chelate compounds, and alkoxide compounds of metals. Examples of the tin compounds include dibutyltin diacetate, dibutyltin dilaurate, dibutyltin dioctoate, dioctyltin diacetate, and dibutyltin dioctoate. Examples of the titanium compound include tetraethoxy titanium, tetraisopropyl titanate, tetrabutyl titanate, diisopropoxy bis(acetylacetonate) titanium, and diisopropoxy bis(ethylacetoacetate) titanium. Examples of the zirconium catalyst include tetrapropoxy zirconium, tetrabutoxy zirconium, tetraacetylacetonate zirconium, and tetraacetylacetonate zirconium. Examples of the zinc compound include zinc acetate, zinc acetylacetonate, zinc octylate, zinc laurate, and zinc naphthenate. Examples of the aluminum compound include aluminum trihydroxide, aluminum tributoxide, aluminum triacetylacetonate, aluminum bis(ethyl acetoacetate) monoacetylacetonate, and aluminum triethylacetoacetate.

Also, various other additives may be added to the condensation-curable silicone resin composition of the present invention as needed. For example, the shrinkage rate during the curing, as well as the thermal expansion coefficient, heat resistance, thermal conductivity, oxidation resistance, and the like of the resulting cured product can be adjusted as needed by various additives. Examples of such additives include non-reinforcing inorganic fillers other than the component (D), such as quartz powder, glass fiber, calcium carbonate, magnesium carbonate, aluminum hydroxide, alumina (aluminum oxide), aluminum nitride, magnesium oxide, and boron nitride, and antioxidants such as hydroquinone, and 2,6-tert-butyl-p-cresol.

### Curing Method

The condensation-curable silicone resin composition of the present invention can be cured after being applied onto the substrate according to the usage, and may be thermally cured preferably at a temperature in a range of 60° C. to 200° C., more preferably in a range of 100° C. to 170° C. If the heating temperature is within the above range, there is no risk of a decrease in adhesion strength between the substrate and the resin cured product. The time of such curing by heating may be 1 to 4 hours, and a step curing method may be employed.

By using specific combinations of the above-described polyorganosiloxane, the condensation-curable silicone resin composition of the present invention ensures superior adhesion property with respect to the substrate compared with ordinary thermosetting silicone resin compositions, and exhibits high adhesion strength even for small-sized LED chips. In addition, although the usage environment of the general addition-curing type, which is produced by using a platinum catalyst, is limited to prevent inhibition of curing due to the nature of the reaction, the condensation-curable silicone resin composition thus developed can be suitably used for various electronic component applications regardless of the environment in which the substrate is used. Specifically, the condensation-curable silicone resin composition can be suitably used as a die attach material for optical semiconductor apparatuses.

### EXAMPLES

The present invention is specifically described below with reference to Examples and Comparative Examples. However, the present invention is not limited to these Examples.

In the following, “part” means “part by mass,” “Me” means “methyl group,” “Vi” means “vinyl group,” “Ep” means “1,2-epoxy-4-ethylcyclohexyl group,” and “Ep′” means “γ-glycidoxypropyl group.”

A “weight average molecular weight” refers to a weight average molecular weight measured by GPC measurement under the conditions described above. In the following Examples, the amount of Si—H group indicates the number of moles of hydrogen atoms directly bonded to silicon atoms in the molecule, and is determined by 1H-NMR measurement using a nuclear magnetic resonance (NMR) measurement equipment (Bruker) using dimethyl sulfoxide (DMSO) as the internal standard.

The following describes each component shown in Tables 1 and 2.

### Component (A)

(a-1) was synthesized as follows:

1,200 g of KC-89RP (Shin-Etsu Chemical Co., Ltd.), 1,200 g of toluene, 163 g of IPA, and 26 g of methanesulfonic acid were added to a reactor, and 289 g of distilled water was added dropwise thereto, followed by a hydrolysis reaction for 100 minutes at room temperature. Then, 26 g of sodium bicarbonate was added for neutralization. Aging was performed while removing by-product alcohol at 72° C. and then residual solvent was removed, thereby synthesizing organopolysiloxane having a weight average molecular weight Mw of 3,900 determined by GPC measurement, represented by the following formula.

CH₃Si(OCH₃)_{0.18}(OH)_{0.013}O_{2.8/2}

### Component (B)

(b-1): Tetraethyl orthosilicate oligomer (Colcoat Co., Ltd.: Ethyl silicate 40, average number of monomer units n=5)
(b-2): Tetramethyl orthosilicate oligomer (Colcoat Co., Ltd.: Methyl silicate 51, average number of monomer units n=4)

### Component (C)

(c-1): Organopolysiloxane of which siloxane units consists of 2 mol % of EpMe₂SiO_{1/2} units, 70 mol % of Me₂Si_{2/2} units, and 28 mol % of HMeSiO_{2/2} units, and weight average molecular weight Mw (measured by GPC) of 6,800 and an epoxy equivalent of 570 g/mol (c=98)
(c-2): Organopolysiloxane of which siloxane units consists of 3 mol % of Ep′SiO_{3/2} units, 84 mol % of Me₂SiO_{2/2} units, and 13 mol % of ViSiO_{3/2} units, a weight average molecular weight of 2,600, and an epoxy equivalent of 950 g/mol
(c-3): An organic compound represented by the following formula synthesized by the method described in the Japanese Translation of PCT International Application Publication No. JP-T-2012-518610

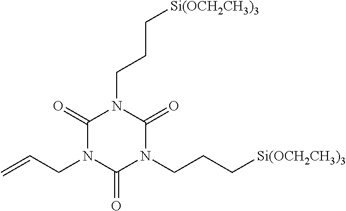

### Component (D)

(d-1): Fumed silica (Aerosil RX-300 manufactured by Nippon Aerosil Co., Ltd.)

### Component (E)

(e-1): Zirconium alkoxide (ZA-65: manufactured by Matsumoto Fine Chemical Co., Ltd.) dissolved in 1-butanol with 2 mass % zirconium content
(e-2): Zirconium chelate (ZC-700: manufactured by Matsumoto Fine Chemical Co., Ltd.) dissolved in toluene with 2 mass % zirconium content
(e-3): Zinc chelate (22% Octope Zn: manufactured by Hope Chemical Co., Ltd) dissolved in toluene with 2 mass % zinc content

### Examples 1 to 5, Comparative Examples 1 to 5

Condensation-curable silicone resin compositions of Examples 1 to 5 and Comparative Examples 1 to 5 were prepared according to the formulation ratios (values are in parts by mass) shown in Tables 1 and 2. The storage stability, heat resistance, contamination resistance, and adhesion property of each of these compositions were evaluated by the test methods described below. Tables 1 and 2 show the measurement results.

### (a) Storage Stability Test

The viscosity of each of the condensation-curable silicone resin compositions thus prepared was measured using a cone and plate rotational viscometer (TVE-33H: Tokisangyo) at a temperature of 23° C. and a rotation rate of 10 rpm in accordance with JIS K 7117-2:1999. The viscosity thus measured was used as the initial value. After storing each condensation-curable silicone resin composition for 24 hours in a sealed condition at 23° C., the viscosity of each composition was measured in the same manner as for the initial value. The ratio of the viscosity measured after storage to the initial viscosity was calculated to determine the pot life.

### (b) Heat Resistance Test

Each of the condensation-curable silicone resin compositions thus prepared was applied to a glass substrate with a thickness of 0.18 mm, followed by heating at 150° C. for 4 hours to produce a cured product. The transmittance of each cured product thus produced was measured at 450 nm using a spectrophotometer (U-410: manufactured by Hitachi High-Tech Corporation), and was used as the initial value. The cured product was then placed in a hot-air circulating dryer having a temperature of 200° C. After allowing it to stand for 48 hours, the direct transmittance was measured in the same manner. The value relative to the initial value as 100% is shown.

### (c) Contamination Resistance Test

One gram of each condensation-curable silicone resin composition prepared above was placed on an aluminum dish, and a 20 mm×20 mm gold-plated substrate was placed on the aluminum dish while preventing it from contacting the resin composition. The aluminum dish was sealed with aluminum foil and heated at 150° C. for 1 hour using a hot-air circulating dryer. After the aluminum dish was taken out from the dryer and cooled to room temperature, the gold-plated surface was visually confirmed. Those with no resin adhering on the gold-plated surface were evaluated as “acceptable (A),” while those with resin adhering on the gold-plated surface were evaluated as “unacceptable (B).”

| | Example [symbol] | Example [symbol] | Example [symbol] | Example [symbol] | Example [symbol] |
|---|---|---|---|---|---|
| [symbol] | [symbol] | [symbol] | [symbol] | [symbol] | [symbol] |

[symbol]

indicates data missing or illegible when filed

### (d) Adhesion Test

A predetermined amount of the condensation-curable silicone resin composition prepared above was applied to the center of each cavity of an SMD 3030 package which has been cleaned by chemical etching after molded, and has a silver-plated lead frame and a EMC reflector member, next the cavity and a small-sized LED chip (BA31U-BM (600 μm×225 μm): manufactured by HC Semitek Co., Ltd.) was die-bonded thereon, followed by heat curing at 150° C. for 4 hours using a hot-air circulating dryer. After the heating, the package was taken out from the dryer and cooled to 25° C., and the adhesion strength between the LED chip and the silver plating was measured for 10 test samples for each condensation-curable silicone resin cured product using a bond tester (Dage 4000: manufactured by Nordson Advanced Technology K.K.), thereby calculating the average adhesion strength. After the measurement, the silver-plated surface was observed under a microscope to evaluate residual resin. Those with 70% or more average residual resin on the silver-plated side in terms of area ratio was evaluated as “acceptable (A),” and those with less than 70% was evaluated as “unacceptable (B).”

TABLE 1

| | | 1 | 2 | 3 | 4 | 5 |
|---|---|---|---|---|---|---|
| A | a-1 | 72.0 | 72.0 | 72.0 | 72.0 | 72.0 |
| B | b-1 | 20.0 | | 20.0 | 20.0 | 20.0 |
| | b-2 | | 20.0 | | | |
| C | c-1 | 3.0 | 3.0 | 3.0 | 3.0 | 3.0 |
| | c-2 | | | | | |
| | c-3 | | | | | |
| D | d-1 | 4.0 | 4.0 | 4.0 | 4.0 | 4.0 |
| E | e-1 | 1.0 | 1.0 | | | |
| | e-2 | | | 1.0 | | |
| | e-3 | | | | 1.0 | |
| Storage | | 1.1 | 1.1 | 1.1 | 1.1 | 1.0 |
| Stability | | | | | | |
| Heat | | 99 | 99 | 98 | 99 | 99 |
| Resistance | | | | | | |
| Contamination | | A | A | A | A | A |
| Resistance | | | | | | |
| Adhesion | Adhesion | 440 | 326 | 379 | 325 | 341 |
| Capability | Strength | | | | | |
| | (gf) | | | | | |
| | Residual | A | A | A | A | A |
| | Resin | | | | | |

TABLE 2

| | | Compar. | Compar. | Compar. | Compar. | Compar. |
|---|---|---|---|---|---|---|
| | | Ex. 1 | Ex. 2 | Ex. 3 | Ex. 4 | Ex. 5 |
| A | a-1 | 72.0 | 72.0 | 72.0 | 92.0 | 95.0 |
| B | b-1 | 20.0 | 20.0 | 20.0 | | |
| | b-2 | | | | | |
| C | c-1 | | | | 3.0 | |
| | c-2 | | 3.0 | | | |
| | c-3 | | | 3.0 | | |
| D | d-1 | 4.0 | 4.0 | 4.0 | 4.0 | 4.0 |
| E | e-1 | 1.0 | 1.0 | 1.0 | 1.0 | 1.0 |
| | e-2 | | | | | |
| | e-3 | | | | | |
| Storage | | 1.1 | 1.1 | 1.1 | 1.3 | 1.3 |
| Stability | | | | | | |
| Heat | | 98 | 99 | 90 | 94 | 95 |
| Resistance | | | | | | |
| Contamination | | A | A | A | A | A |
| Resistance | | | | | | |
| Adhesion | Adhesion | 95 | 58 | 90 | 301 | 197 |
| Capability | Strength | | | | | |
| | (gf) | | | | | |
| | Residual | B | B | B | B | B |
| | Resin | | | | | |

As a result of the evaluation test described above, the condensation-curable silicone resin compositions of the present invention (Examples 1 to 5) have excellent storage stability, heat resistance, and contamination resistance, and, in the LED chip adhesion test, they exhibited high adhesion strength and desirable fracture mode showing cohesive failure.

On the other hand, Comparative Example 1 prepared without the component (C), Comparative Example 5 prepared without the component (B) and the component (C), and Comparative Example 2 ((c-2)) and Comparative Example 3 ((c-3)) containing the component (c-2) and the component (c-3), which are different from the component (C) of the present invention, showed significantly lower adhesion strength than those of Examples 1 to 5. Further, Comparative Example 4, which was prepared using the component (C) ((c-1)) of the present invention but not using the component (B), also showed lower adhesion strength than those of Examples 1 to 5.

This revealed that the condensation-curable silicone resin compositions of the present invention have excellent adhesion capability with respect to substrates, exhibit high adhesion strength even for small-sized LED chips, and that they can be suitably used for various electronic component applications regardless of the environment in which the substrate is used. Specifically, it was revealed that the condensation-curable silicone resin compositions of the present invention can be suitably used as die attach materials for optical apparatuses.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A condensation-curable silicone resin composition, comprising:
(A) a polyorganosiloxane having hydroxyl group and hydrolysable group represented by the following formula (1), in an amount of 100 parts by mass,
CH₃Si(OR)ₐ(OH)_{b}O_{(3-a-b)/2} (1)
wherein R represents a same or different alkyl group having 1 to 6 carbon atoms, and satisfies 0≤a≤0.4, 0.001≤b≤0.5, 0.001≤a+b≤0.9;
(B) an organosilicate oligomer, which is a partially hydrolyzed condensate of tetraalkyl orthosilicate, in an amount of 10 to 50 parts by mass relative to 100 parts by mass of the component (A);
(C) a linear polyorganosiloxane having epoxy group and hydrosilyl group in the molecule represented by the following formula (2), in an amount of 0.1 to 10 parts by mass relative to 100 parts by mass of total of component (A) and component (B), 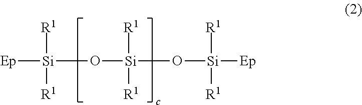
wherein R¹ is independently a hydrogen atom, an alkyl group having 1 to 12 carbon atoms, or an epoxy-containing organic group; c is a number satisfying 1≤c≤260; and Ep is independently an organic group having one or more epoxy groups in a substituent, provided that at least one of the R¹ is a hydrogen atom; and
(D) an inorganic filler in an amount of 1 to 10 parts by mass relative to 100 parts by mass of the component (A).

2. The condensation-curable silicone resin composition according to claim 1, wherein the alkyl group of the tetraalkyl orthosilicate of the component (B) has 1 to 6 carbon atoms.

3. The condensation-curable silicone resin composition according to claim 1, wherein the component (C) has a weight average molecular weight of 1,000 to 20,000 and an epoxy equivalent of 400 to 650 g/mol.

4. The condensation-curable silicone resin composition according to claim 1, further comprising (E) a condensation-curing catalyst.

5. A die attach material for an optical semiconductor apparatus, comprising the condensation-curable silicone resin composition according to claim 1.
